(19) United States
(12) Patent Application Publication
(10) Pub. No.: US 2015/0321387 A1
(43) Pub. Date: Nov. 12, 2015

(54) METHOD OF MANUFACTURING LIGHT EMITTING DEVICE

(71) Applicants: David J. Bravet, Westborough, MA (US); Michael A. Adamko, Morristown, NJ (US)

(72) Inventors: David J. Bravet, Westborough, MA (US); Michael A. Adamko, Morristown, NJ (US)

(21) Appl. No.: 14/394,392

(22) PCT Filed: Sep. 4, 2012
(86) PCT No.: PCT/US12/53706

§ 371 Date: Apr. 20, 2015

Related U.S. Application Data
(60) Provisional application No. 61/623,488, filed on Apr. 12, 2012.

(51) Int. Cl. B29C 33/68; C08J 5/18; B29C 33/62; H01L 33/54; H01L 25/075

(52) U.S. Cl. CPC B29C 33/68; H01L 33/54; H01L 25/0753; B29C 33/62; C08J 5/18; H01L 2933/005; B29L 2031/34

(57) ABSTRACT

A novel method of producing an encapsulated light emitting device. A preferred mold release film that can be used during the encapsulation of a LED chip has an elastic modulus and a glass transition temperature that are low enough as compared to the desired molding temperature that the release film will closely conform to the interior of the molding cavities used to form a protective lens surrounding an LED chip. A preferred release film according to embodiments of the present invention comprises a fully fluorinated polymer, such as a perfluoroalkoxy polymer, including MFA, or fluorinated ethylene propylene.

### TECHNICAL FIELD OF THE INVENTION

The present invention relates to manufacturing a light emitting device and more particularly to the use of a mold release film during the manufacture on an encapsulated light emitting diode.

### BACKGROUND OF THE INVENTION

A light emitting diode (LED) is a solid-state, semiconductor light source having a number of advantages over more traditional incandescent light bulbs and fluorescent lamps. Some of the advantages of LEDs include low power consumption, small size, faster on/off times, low heat radiation, long useful life, shock resistance, and a simple fabrication process. Production of LED devices continues to increase with increasing demand, partly driven by utilization of LED devices in new applications.

A conventional LED generally comprises a semiconductor chip; an encapsulant, often made of epoxy or silicone; and electrical connection elements comprising two fine gold wires bonded to the contacts and connected to two metal pins emerging from the envelope. The semiconductor chip is doped to create a p-n junction so that current will flow easily from the p-side, or anode, to the n-side, or cathode, thus forming a diode. As current flows across the diode, the movement of electrons and electron holes causes the release of energy in the form of photons.

FIG. 1 is a diagram of a conventional LED, which includes diode 102, having the structure described above, two external electrodes 104 (connected to the cathode) and 106 (connected to the anode), and an encapsulant 110, mounted on a substrate 112. The encapsulant serves several functions, including protecting the diode and electrical connections against oxidation and moisture, improving shock resistance, and acting as a diffusing element or lens for light produced by the LED.

A typical fabrication process is shown in FIG. 2, described below, in which encapsulated LED devices are produced using multi-cavity molds to form the encapsulating lens. Applicants have discovered that the release film is a significant component with respect to a variety of possible manufacturing defects for such lenses. It is known to use ethylene tetrafluoroethylene (ETFE) film as a mold release film for LED encapsulation. However, ETFE film is available only from a limited number of suppliers. Further, not all ETFE film is suitable for use as a mold release film.

What is needed is an alternative mold release film for use during LED encapsulation and fabrication. Embodiments of the present invention thus relate to a mold release film that meets the requirements of industry in terms of yield and fabrication costs, while also enlarging the range of products available for LED fabrication.

### SUMMARY OF THE INVENTION

A preferred embodiment of the present invention is directed to a novel method of producing an encapsulated light emitting device. A preferred mold release film that can be used during the encapsulation of a LED chip has an elastic modulus and a glass transition temperature that are low enough as compared to the desired molding temperature that the release film will closely conform to the interior of the molding cavities used to form a protective lens surrounding an LED chip.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more thorough understanding of the present invention, and advantages thereof, reference is now made to the following descriptions taken in conjunction with the accompanying drawings, in which:

FIG. 1 is a diagram of a conventional prior art LED;

FIG. 2 shows a prior art method of forming encapsulated LED devices using multi-cavity molds to form the encapsulating lens;

FIG. 3 is a flow chart showing the steps in a method of producing an encapsulated light emitting device according to preferred embodiments of the present invention; and

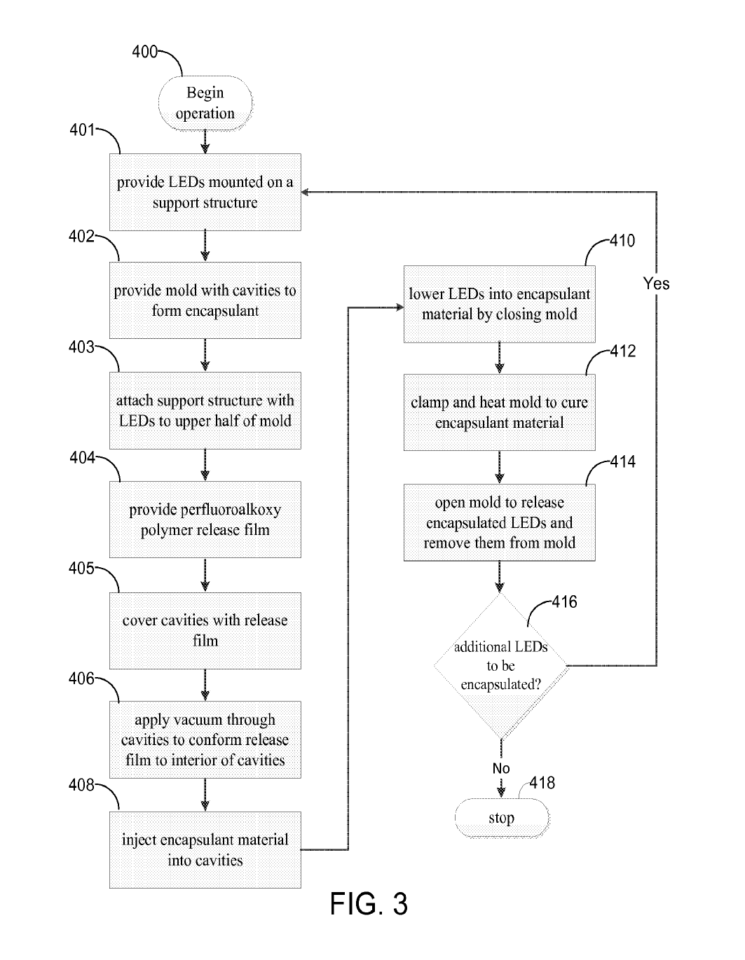

FIG. 4 shows a prior art mold that could be used to practice embodiments of the present invention.

The accompanying drawings are not intended to be drawn to scale. In the drawings, each identical or nearly identical component that is illustrated in various figures is represented by a like numeral. For purposes of clarity, not every component may be labeled in every drawing.

### DETAILED DESCRIPTION OF PREFERRED EMBODIMENTS

Preferred embodiments of the present invention are directed at a novel method of producing an encapsulated light emitting device. A typical fabrication process for LED devices involves encapsulating the LED itself within a dome-shaped lens of epoxy or silicone. The encapsulating material, also referred to as potting material, not only protects the LED from damage due to moisture, shock, etc., the encapsulating material must also be adequately transmit the desired wavelengths of light. The degree to which light is transmitted by the encapsulant (lens) is an important consideration in choosing an encapsulating material. Unfortunately, some amount of the light generated by the LED chip will always be trapped within the encapsulating material due to the refractive index of the material and the degree of total internal reflection. This trapped light undesirably reduces or otherwise alters the light output of the LED device.

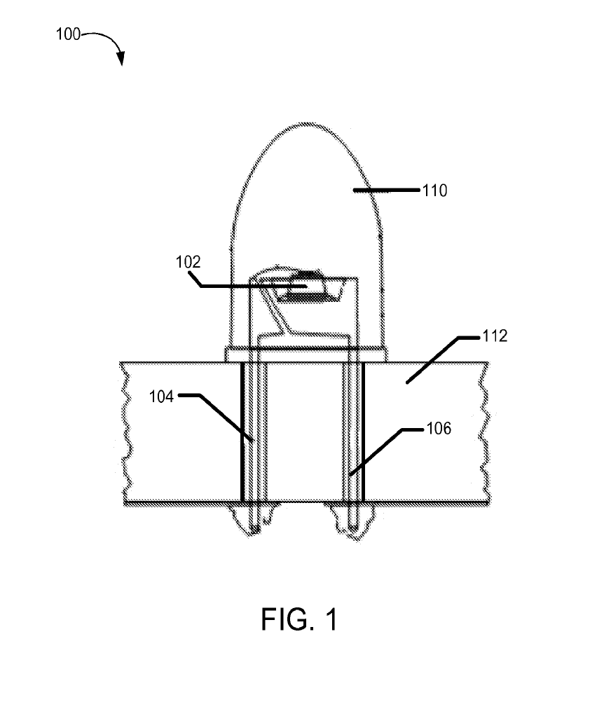

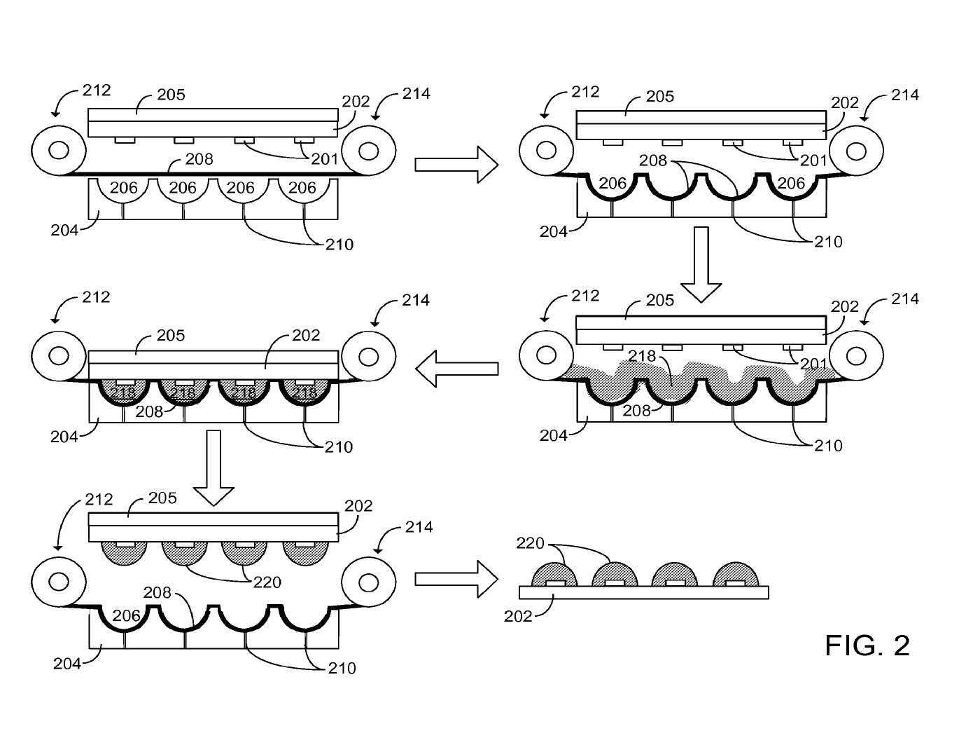

FIG. 2 shows a prior art method of forming encapsulated LED devices using multi-cavity molds to form the encapsulating lens. First, the prior art method comprises providing a plurality of light emitting elements 201 mounted on a support structure 202, such as an LED chip mounted on a PCB substrate. A mold with an upper surface 205 and a lower surface 204 is also provided. Lower surface 204 preferably has a plurality of cavities 206, with the arrangement of cavities corresponding to the arrangement of LED chips on the substrate. The shape of the cavities defines the shape of the encapsulant or lens to be formed around the corresponding light emitting elements. Typically, the cavities are shaped to produce a dome-shaped lens, such as the one shown in FIG. 1. The substrate, such as the PCB, is fixed in place (usually by application of a vacuum) on the upper mold surface with the LED chips facing the cavities in the lower half of the mold.

The cavities 206 are then covered by a flexible sacrificial mold release film 208, which serves to prevent the encapsulating material from adhering to the inside of the mold cavities, thus allowing the mold to be re-used, and also to prevent damage to the lens when the lens and mold are separated. The release film is conformed to the inside of the cavities, usually by the application of a vacuum through a vacuum pathway 210 in each cavity. Once the vacuum is applied, the release film will be pulled into the cavities to completely cover the interior surface of the cavities. One common release film used in the prior art is formed from the fluoropolymer ETFE. The release film can be supplied from a roll 212 of unused release film, with the used release film wound onto a take-up reel 214.

Next, an encapsulating material 218 (also referred to as a potting material) is introduced into the cavities. Typical encapsulating materials include epoxies and silicone resin. Under a partial vacuum, the LED chips or other light emitting devices 201 are then pressed into the encapsulating material so that the encapsulating material 218 fills all of the space inside the cavities 206. The mold is then clamped and heated (for example, to 100-150° C. for 3-10 minutes) to cure the encapsulant material. The mold can then be released and the encapsulated LED devices 220 removed from the mold. The used release film can be removed from the cavities, usually by winding the used film onto the take-off roller 214 while a continuous portion of unused film 208 is rolled over the cavities so that the encapsulation process can be repeated.

Molding equipment suitable for carrying out the process of FIG. 2 is available, for example, from TOWA Corporation of Kyoto, Japan; high-brightness LED chips are available, for example, from Lextar Electronics Corporation of Hsinchu, Taiwan; and suitable silicone resin for use as an encapsulating material is available, for example, from Dow Corning of Midland, Mich., US.

Applicants have discovered that the release film plays a surprisingly important role in the fabrication of encapsulated light emitting devices, especially in regard to reducing manufacturing failures and maintaining commercially acceptable yields for the manufacturing process. Failures related to release film can include peeling and/or crumbling of the lens surface after demolding. In some cases, observed defects can include deformation of the lens, sometimes referred to as a “cat-eye” defect because the distorted lens shape often resembles a cat's eye rather than the intended clear dome shape. These types of defects in encapsulated LED lenses are seen even with prior art ETFE release films. Such defects affect the light transmission of an encapsulated LED and can render it unusable. Obviously, a high yield rate (low incidence of failures) is very desirable from a commercial standpoint.

Although such defects have long been observed during encapsulated LED manufacturing, applicants now believe that the source of these defects is poor conformity of the release film to the mold cavity. Applicants have also discovered that characteristics like tensile strength and dimensional stability surprisingly do not appear to have a strong correlation to observed lens defects. Instead, Applicants believe that the elastic modulus and glass transition temperatures are more significant factors. Applicants note, however, that although a theoretical basis for the success of the invention is described herein, the invention has been shown to work for the release film polymers described below, regardless of the accuracy of the theory.

A preferred mold release film according to the present invention will thus have an elastic modulus (E) at the mold temperatures that is low enough for the preferred material to be elastic enough to conform completely to the inside of the cavities. A preferred mold release film will have an elastic modulus at 150° C. of no more than 50 MPa, more preferably no more than 35 MPa, even more preferably no more than 30 MPa, and still more preferably no more than 25 MPa. Additionally, a preferred mold release film according to the present invention will have a glass transition temperature (T_{g}) that is low enough for the material to have reached the rubber plateau, but not so low that the material reaches its melting point. A preferred mold release film will have a glass transition temperature of less than 100° C., more preferably less than 90° C., but with a melting point above the highest operating temperature of the mold, for example above 200° C.

Additionally, Applicants believe that contact angle with water is also a significant characteristic of a preferred mold release film. Generally speaking, the higher the contact angle, the lower the surface energy of the release film and the lower the ability of the film to interact with or adhere to the encapsulant. A preferred mold release film will have a contact angle of at least 93 degrees, more preferably of at least 95 degrees. The adhesion forces between the release film and the encapsulant will also be minimized by using a film having a lower surface energy. The surface energy of ETFE, a commonly used release film for LED lens manufacturing, is approximately 25 dynes/cm. A preferred release film according to some embodiments of the present invention will have a surface energy that is less than 25 dynes/cm, more preferably less than 20 dynes/cm.

Although less significant from the perspective of solving the problem of the previously unexplained encapsulation failures, there are also a number of other characteristics that are desirable for a release film according to the present invention. As an example, a mold release film according to the present invention preferably has a tensile strength of greater than 20 MPa and an elongation-at-break at 150° C. of greater than 200%. This provides the mold release film with a sufficient amount of strength and resiliency so that even when the film is deformed (as when it in conformed to the interior of the cavities) cracking, tearing, and overstretching can be prevented. Also, for the same reasons, a preferred mold release film will be thick enough that the film will be strong enough to avoid being unduly damaged during the manufacturing process even where the tensile strength and elongation-at-break are as described above. An example of a suitable thickness would be at least 3 mils.

Finally, Applicants have also determined that it is desirable that the mold release film have a surface that is as smooth as possible in order to produce a lens having a surface that is as smooth as possible. As discussed above, a rougher surface on the LED lens can contribute to light scattering, which can reduce the effectiveness of an LED light source. A preferred mold release film will have an average surface roughness (Sa) of 0.20 μm or less, more preferably of 0.15 μm or less, and even more preferably of 0.10 μm or less.

One exemplary group of materials that matches desired characteristics discussed above and which could be formed into a suitable mold release film would include certain fully fluorinated thermoplastic polymers such as perfluoroalkoxy polymers, specifically perfluoro methyl alkoxy (MFA). MFA comprises a perfluoroalkoxy polymer formed from polymerization of at least tetrafluoroethylene (TFE) and perfluoromethyl vinyl ether (PMVE). With respect to the preferred characteristics described above, MFA has an elastic modulus at 150° C. of 17.3 MPa, and a glass transition temperature of approximately 86.7° C. Based upon testing done by Applicants, a preferred mold release film formed from MFA is capable of conforming very closely to the interior of a mold cavity.

Another example of a suitable fully fluorinated thermoplastic polymer would be fluorinated ethylene propylene (FEP). With respect to the preferred characteristics described above, FEP has an elastic modulus at 150° C. of 48-50 MPa, and a glass transition temperature of approximately 70° C. to 140° C., depending on the exact resin being tested. Based these values, a preferred mold release film formed from FEP would also be capable of conforming very closely to the interior of a mold cavity.

The following chart summarizes other relevant characteristics of MFA and FEP (although measured values may vary to some degree for different manufacturers or grades).

| | Contact | | | Tensile | | Surface Energy |
|---|---|---|---|---|---|---|
| Material | angle | Sa | Tm (° C.) | strength | Elongation | (dynes/cm) |
| MFA | 97° | 0.07 | 265-275 | 21 MPa | >300% (150° C.) | 17 |
| | | (+/−0.01) | | | 238% (23° C.) | |
| FEP | 114° | Not available | 265-275 | 20-26 MPa | 390% (150° C.) | 16 |
| | | | | | 350% (23° C.) | |

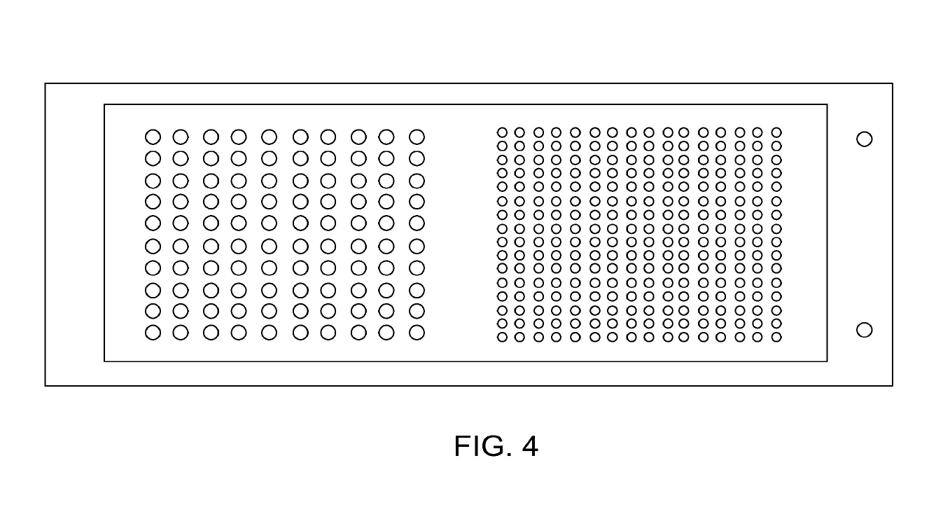

FIG. 4 is a flow chart showing the steps in a method of producing an encapsulated light emitting device according to preferred embodiments of the present invention. The materials and steps for practicing preferred embodiments of the present invention are the same as for the prior art process described in FIG. 2 with the exception of the novel mold release film used. In the method of FIG. 4, the manufacturing operation begins in step 400. Next, in step 401, a plurality of non-encapsulated light emitting elements mounted on a support structure is provided. In preferred embodiments of the present invention, an LED chip mounted on a PCB substrate is used. The LED chip can be of any type or color. Embodiments of the present invention are also suitable for use with high-brightness LEDs. Although this method could be practiced using a single light emitting element, in most cases a large number of LEDs would be processed simultaneously.

In step 402, a mold having a plurality of cavities that define a shape of an encapsulant to be formed around the light emitting element is provided. Typically, the cavities will produce a dome-shaped lens, such as the one shown in FIG. 1, but any desired shape could be used. As with FIG. 2 above, the arrangement of LED devices on the substrate should correspond to the arrangement of cavities in the lower half of the mold so that each LED can be placed in a separate cavity. The substrate, such as the PCB, is then fixed in place (usually by application of a vacuum) on the upper mold surface in step 403 with the LED chips facing the cavities in the lower half of the mold. An example of the lower portion of a mold 504 suitable for use with embodiments of the present invention is shown in FIG. 5. Lower mold portion 504 has cavities for forming two different sizes of LED lenses. For example, larger cavities 550 could be used to form lenses having a diameter of 2.5 mm, while smaller cavities 552 could be used to form lenses having a diameter of 1.8 mm.

In step 404, a release film is provided and placed over the cavities, a preferred release film according to embodiments of the present invention comprising a fully fluorinated polymer, such as, for example, a perfluoroalkoxy polymer, including MFA, or fluorinated ethylene propylene. In step 406, the mold release film is conformed to the inside of the cavities, preferably by was of a vacuum pressure applied to each cavity that pulls the release film down into each of the cavities. Next, in step 408, an encapsulating material such as a resin (potting material) is introduced into each of the cavities. In some preferred embodiments, the encapsulating material can be injected into the cavities of the lower half of the mold from a runner or nozzle. The release film fitting to the interior walls of the cavities prevents the encapsulating material from contacting the interior of the cavities.

In step 410, the light emitting elements are positioned so that they are within the cavities and surrounded by the encapsulating material. This can be accomplished by closing the mold, which causes the light emitting elements (such as LED chips) to be pressed down into the encapsulating material, thus causing the encapsulating material to fill the cavities.

In step 412, the mold is then clamped and heated (for example, to 100-150° C. for 3-10 minutes) to cure the encapsulant material. Once the cure is complete, in step 414, the mold can then be released and the encapsulated LED device removed from the mold. If additional LEDs are to be encapsulated 416, the process returns to step 401; if not, the manufacturing process is terminated in step 418.

A preferred embodiment of the present invention is thus directed at a method of producing an encapsulated light emitting device, the method comprising:
providing a plurality of non-encapsulated light emitting elements mounted on a support structure;
providing a mold having a plurality of cavities that define a shape of an encapsulant to be formed around the light emitting element;
providing a release film covering the cavities, the release film comprising a fully fluorinated polymer;
conforming the release film to the interior of the cavities;
introducing a potting material into the space within the cavities, the release film preventing the potting material from contacting the interior of the cavities;
positioning the non-encapsulated light emitting elements so that they are within the cavities and surrounded by the potting material;
curing the potting material in the space between the light emitting elements and the release film in the cavities to encapsulate the light emitting elements; and
freeing the encapsulated light emitting elements from the mold and the release film.

According to another preferred embodiment, a method of manufacturing a light emitting device including a light emitting element encapsulated by a resin lens comprises:
providing a light emitting element mounted on a support structure;
providing a mold having a cavity that defines a shape of a lens to be formed around the light emitting element;
providing a release film covering the cavity, the release film comprising a perfluoroalkoxy polymer or fluorinated ethylene propylene;
conforming the release film to the interior of the cavity;
introducing a resin into the space within the cavity, the release film preventing the resin from contacting the interior of the cavity;
positioning the light emitting element so that it is within the cavity and surrounded by the resin;
curing the resin in the space between the light emitting element and the release film in the cavity to form a lens encapsulating the light emitting element; and
freeing the light emitting device from the mold and the release film.

According to another preferred embodiment, an apparatus for manufacturing a light emitting device comprises:
a mold having a plurality of cavities that define a lens shape;
winding reels for scrolling a mold release film over the plurality of cavities;
a dispenser for introducing a silicone resin into the plurality of cavities;
a vacuum system for applying a vacuum to the plurality of cavities to form the release film to the interior of the cavities; and
a supply of a mold release film, the mold release film comprising a roll of a fully fluorinated polymer film.

According to another preferred embodiment, a method of producing an encapsulated light emitting device comprises:
providing a plurality of non-encapsulated light emitting elements mounted on a support structure;
providing a mold having a plurality of cavities that define a shape of an encapsulant to be formed from a heat-curable resin around the light emitting element;
providing a release film covering the cavities, the release film selected from a group of fluorinated polymers having an elastic modulus of 50 MPa or less at 150° C., a glass transition temperature that is below the curing temperature of the heat-curable resin, a contact angle with water of at least 95 degrees, and a surface energy that is less than 25 dynes/cm;
conforming the release film to the interior of the cavities;
introducing a heat-curable resin into the space within the cavities, the release film preventing the potting material from contacting the interior of the cavities;
positioning the non-encapsulated light emitting elements so that they are within the cavities and surrounded by the heat-curable resin;
curing the heat-curable resin in the space between the light emitting elements and the release film in the cavities by heating the mold to the curing temperature of the resin; and
freeing the encapsulated light emitting elements from the mold and the release film.

In preferred embodiments of the present invention the light emitting device can comprise a light emitting diode (LED), a visible light LED, a through-hole LED, a surface mount LED, a high-brightness LED, or an organic LED. Also, the resin or potting material can comprise an epoxy or silicone.

In preferred embodiments of the present invention conforming the release film to the interior of the cavities can comprise applying a vacuum to the cavities through a vacuum port to fit the release film to the interior of the cavities.

In preferred embodiments of the present invention the fluorinated polymer can comprise perfluoro methyl alkoxy (MFA), fluorinated ethylene propylene (FEP), and/or a perfluoroalkoxy polymer formed from polymerization of at least tetrafluoroethylene (TEL) and perfluoromethyl vinyl ether (PMVE). Also, the fluorinated polymer can have a contact angle with water of at least 93 degrees or a contact angle with water of at least 95 degrees. The fluorinated polymer can have an elastic modulus at 150° C. of no more than 50 MPa, no more than 35 MPa, no more than 30 MPa, or no more than 25 MPa. The fluorinated polymer has a glass transition temperature of less than 100° C. or less than 90° C. and a surface energy that is less than 25 dynes/cm or less than 20 dynes/cm.

In preferred embodiments of the present invention the release film comprises a fluorinated polymer has an average surface roughness of 0.20 μm or less, an average surface roughness of 0.15 μm or less, or an average surface roughness of 0.10 μm or less. The release film can also comprise a roll of fully fluorinated polymer film, the fully fluorinated polymer having a melting temperature of greater than 200° C., a tensile strength of 20 MPa or greater, and an elongation-at-break at 150° C. of greater than 300%. In preferred embodiments, the release film comprises a fully fluorinated polymer having an elastic modulus at 150° C. of no more than 50 MPa, no more than 35 MPa, no more than 30 MPa, or no more than 25 MPa. In preferred embodiments, the release film comprises a fully fluorinated polymer having a glass transition temperature of less than 100° C. or less than 90° C. The release film can also comprise a fully fluorinated polymer having an average surface roughness of 0.20 μm or less, an average surface roughness of 0.15 μm or less, or an average surface roughness of 0.10 μm or less. The release film can also comprise a fully fluorinated polymer having a surface energy that is less than 25 dynes/cm or less than 20 dynes/cm. In preferred embodiments the fully fluorinated polymer comprises MFA or FEP.

Other preferred embodiments of the invention are directed at a mold release film for use in molding a silicon lens to encapsulate a light emitting diode in which the mold release film comprises a fluorinated polymer film having a glass transition temperature of less than 100° C.; an elastic modulus at 150° C. of no more than 50 MPa; and an average surface roughness of 0.20 μm or less. In preferred embodiments, the fluorinated polymer film has a glass transition temperature of less than 90° C. The fluorinated polymer film can have an elastic modulus at 150° C. of no more than 35 MPa, no more than 30 MPa, or no more than 25 MPa. The fluorinated polymer film can have an average surface roughness of 0.15 μm or less, or 0.10 μm or less. The fluorinated polymer film can comprise a fully fluorinated thermoplastic polymer film. The fluorinated polymer film has a contact angle with water of at least 93 degrees, or of at least 95 degrees.

In any of the embodiments described above, the fluorinated polymer film can comprise a perfluoroalkoxy polymer formed from polymerization of at least tetrafluoroethylene (TEE) and perfluoromethyl vinyl ether (PMVE), perfluoro methyl alkoxy (MFA), and/or fluorinated ethylene propylene (FEP). In some preferred embodiments, the release film, as described in any of the specific embodiments above, can have a thickness of no more than 3 mils.

Preferred embodiments of the present invention also include a light emitting device made by any of the methods described herein.

The invention described herein has broad applicability and can provide many benefits as described and shown in the examples above. The embodiments will vary greatly depending upon the specific application, and not every embodiment will provide all of the benefits and meet all of the objectives that are achievable by the invention. Release film material suitable for carrying out the present invention, such as MFA, is commercially available, for example, from the assignee of the present application.

In the following discussion and in the claims, the terms “including” and “comprising” are used in an open-ended fashion, and thus should be interpreted to mean “including, but not limited to . . . . ” To the extent that any term is not specially defined in this specification, the intent is that the term is to be given its plain and ordinary meaning. The accompanying drawings are intended to aid in understanding the present invention and, unless otherwise indicated, are not drawn to scale.

Although the present invention and its advantages have been described in detail, it should be understood that various changes, substitutions and alterations can be made to the embodiments described herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

We claim as follows:

1-49. (canceled)

50. A method of producing an encapsulated light emitting device, the method comprising:
providing a plurality of non-encapsulated light emitting elements mounted on a support structure;
providing a mold having a plurality of cavities that define a shape of an encapsulant to be formed around the light emitting element;
providing a release film covering the cavities, the release film comprising a fully fluorinated polymer;
conforming the release film to the interior of the cavities;
introducing a resin into the space within the cavities, the release film preventing the resin from contacting the interior of the cavities;
positioning the non-encapsulated light emitting elements so that they are within the cavities and surrounded by the resin;
curing the resin in the space between the light emitting elements and the release film in the cavities to encapsulate the light emitting elements; and
freeing the encapsulated light emitting elements from the mold and the release film.

51. The method of claim 50 in which the light emitting device comprises a light emitting diode (LED), a visible light LED, a through-hole LED, a surface mount LED, a high-brightness LED, or an organic LED.

52. The method of claim 50 in which the fluorinated polymer comprises a perfluoroalkoxy polymer formed from polymerization of at least tetrafluoroethylene (TFE) and perfluoromethyl vinyl ether (PMVE).

53. The method of claim 50 in which the fluorinated polymer comprises perfluoro methyl alkoxy (MFA) or fluorinated ethylene propylene (FEP).

54. The method of claim 50 in which the fluorinated polymer has a contact angle with water of at least 93 degrees.

55. The method of claim 50 in which the fluorinated polymer has an elastic modulus at 150° C. of no more than 50 MPa and a glass transition temperature of less than 100° C.

56. The method of claim 50 in which the fluorinated polymer has a surface energy that is less than 25 dynes/cm.

57. The method of claim 50 in which the release film comprising a fluorinated polymer has an average surface roughness of 0.20 μm or less.

58. The method of claim 50 in which the resin comprises a heat-curable resin and in which the fluorinated polymer has a glass transition temperature that is below the curing temperature of the heat-curable resin.

59. A mold release film for use in manufacturing a light emitting device, the mold release film comprising a fluorinated polymer film having a glass transition temperature of less than 100° C.; an elastic modulus at 150° C. of no more than 50 MPa.

60. The mold release film of claim 59 in which the fluorinated polymer film has an average surface roughness of 0.20 μm or less.

61. The mold release film of claim 59 in which the fluorinated polymer film comprises a fully fluorinated thermoplastic polymer film.

62. The mold release film of claim 59 in which the fluorinated polymer film has a contact angle with water of at least 93 degrees.

63. The mold release film of claim 59 in which the fluorinated polymer film comprises a perfluoroalkoxy polymer formed from polymerization of at least tetrafluoroethylene (TFE) and perfluoromethyl vinyl ether (PMVE).

64. The mold release film of claim 59 in which the fluorinated polymer film comprises perfluoro methyl alkoxy (MFA) fluorinated ethylene propylene (FEP).

65. An apparatus for manufacturing a light emitting device, the apparatus comprising:
a mold having a plurality of cavities that define a lens shape;
winding reels for scrolling a mold release film over the plurality of cavities;
a dispenser for introducing a silicone resin into the plurality of cavities;
a vacuum system for applying a vacuum to the plurality of cavities to form the release film to the interior of the cavities; and
a supply of a mold release film, the mold release film comprising a roll of a fully fluorinated polymer film.

66. The apparatus of claim 65 in which the light emitting device comprises a light emitting diode (LED), a visible light LED, a through-hole LED, a surface mount LED, a high-brightness LED, or an organic LED.

67. The apparatus of claim 65 in which the fluorinated polymer comprises a perfluoroalkoxy polymer formed from polymerization of at least tetrafluoroethylene (TFE) and perfluoromethyl vinyl ether (PMVE).

68. The apparatus of claim 65 in which the fluorinated polymer comprises perfluoro methyl alkoxy (MFA) or fluorinated ethylene propylene (FEP).

69. The apparatus of claim 65 in which the fluorinated polymer has a contact angle with water of at least 93 degrees.
